(19) United States
(12) Patent Application Publication
(10) Pub. No.: US 2024/0372329 A1
(43) Pub. Date: Nov. 7, 2024

(54) LASER APPARATUS

(71) Applicant: TRUMPF Photonic Components GmbH, Ulm (DE)

(72) Inventors: Roman Koerner, Lonsee (DE); Alexander Weigl, Guenzburg (DE)

(21) Appl. No.: 18/776,278

(22) Filed: Jul. 18, 2024

Related U.S. Application Data
(63) Continuation of application No. PCT/EP2023/050992, filed on Jan. 17, 2023.

(30) Foreign Application Priority Data
Jan. 21, 2022 (DE) 10 2022 101 442.8

(51) Int. Cl. H01S 5/183; H01S 5/042; H01S 5/20; H01S 5/22

(52) U.S. Cl. CPC H01S 5/18361; H01S 5/0422; H01S 5/2009; H01S 5/22

(57) ABSTRACT

A semiconductor component for emitting laser light includes a main body having at least one mesa portion with an emission region for the laser light. The emission region includes a first mirror portion, a second mirror portion, and an active portion arranged between the first mirror portion and the second mirror portion. The active portion serves to generate the laser light. The semiconductor component further includes electrical contacts for feeding electrical energy into the active portion, and a metallic polarization grating arranged on a surface of the main body on the emission region.

### CROSS REFERENCE TO RELATED APPLICATIONS

This application is a continuation of International Application No. PCT/EP2023/050992 (WO 2023/139057 A1), filed on Jan. 17, 2023, and claims benefit to German Patent Application No. DE 10 2022 101 442.8, filed on Jan. 21, 2022. The aforementioned applications are hereby incorporated by reference herein.

### FIELD

Embodiments of the present invention relate to a semiconductor component for emitting laser light.

### BACKGROUND

Vertical cavity surface emitting lasers (VCSELs) are known which emit unpolarized laser light. Therefore, such conventional semiconductor lasers are equipped with polarization devices that are intended to impart a stationary polarization to the laser light. These polarization devices are usually incorporated in the semiconductor laser by way of complex preparation steps. For example, a polarization grating etched into a surface of the semiconductor laser is embodied. Such a polarization grating can affect the reflectivity of a resonator cavity on which the semiconductor laser is based and which is formed by highly reflective mirrors. The laser light is generated in the resonator cavity.

The known semiconductor lasers are often combined with photodiodes in order to detect reflected laser light or laser light from further semiconductor lasers. The photodiode respectively assigned to a semiconductor laser may be an integral part of the semiconductor laser and may be arranged downstream of the resonator cavity in the direction of incidence of the laser light to be detected, for example. The photodiode is a component that is produced separately and connected to the semiconductor laser. This presupposes a large number of additional production steps.

### SUMMARY

Embodiments of the present invention provide a semiconductor component for emitting laser light. The semiconductor component includes a main body having at least one mesa portion with an emission region for the laser light. The emission region includes a first mirror portion, a second mirror portion, and an active portion arranged between the first mirror portion and the second mirror portion. The active portion serves to generate the laser light. The semiconductor component further includes electrical contacts for feeding electrical energy into the active portion, and a metallic polarization grating arranged on a surface of the main body on the emission region.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a semiconductor component comprising a polarization grating on an emission region according to some embodiments;

FIG. 2 shows a polarization grating separated from electrical contacts of the semiconductor component according to some embodiments;

FIG. 3 shows a polarization grating having a meanderlike form according to some embodiments;

FIG. 4 shows a polarization grating having a connection to electrical contacts of the semiconductor component, according to some embodiments; and

FIG. 5 shows a polarization grating formed from two intermeshing comblike polarization gratings, according to some embodiments.

### DETAILED DESCRIPTION

Embodiments of the invention provide a semiconductor component for emitting laser light which has an improved efficiency of the resonator cavity and at the same time is cost-effective to produce.

According to some embodiments, a semiconductor component for emitting laser light has a main body having at least one mesa portion with an emission region for the laser light, which is assigned a first mirror portion, a second mirror portion and an active portion arranged between the two mirror portions and serving to generate the laser light. The semiconductor component comprises electrical contacts for feeding electrical energy into the active portion, and a metallic polarization grating being arranged on a surface of the main body on the emission region.

The two mirror portions form a resonator cavity, in which the active layer is excited to emit laser light. The laser light contained in the resonator cavity is emitted from the emission region as coherent laser light. At least one subsection of the resonator cavity is comprised by the mesa portion.

The polarization grating enables a polarization of the emitted laser light which is permanent and temperature-independent.

The metallic polarization grating is arranged on the surface of the main body and can be produced in a production step identical or similar to that for the electrical contacts. This makes possible a production method which, by comparison with the conventional production method, has fewer steps and can be carried out more rapidly and more cost-effectively as a result.

Advantageously, the polarization grating has a mirror surface facing the surface, said mirror surface reflecting the laser light in addition to the mirror portions. The mirror surface reflects the laser light into the main body and increases the reflectivity of the resonator cavity. The mirror surface has a very high surface quality, which more or less preferably corresponds to the surface quality of the surface of the main body, with the result that a high inherent reflectivity is attained. This is achieved in particular by virtue of the mirror surface bearing on the surface, without the material on which the mirror surface is based diffusing appreciatively into the surface.

Furthermore, provision can be made for the surface to be provided with a dielectric coating, such that the polarization grating bears on the coating. This ensures a high surface quality of the mirror surface since the dielectric coating makes it more difficult for the material on which the mirror surface is based to diffuse into the coated surface by comparison with an uncoated surface. In particular, in this way a surface quality is ensured over a longer period of time than in the case of an uncoated surface. The coating can advantageously be applied by way of an oxidation process and/or an atomic layer coating method.

One particular development can include an electron potential barrier being embodied between the polarization grating and the main body, such that a Schottky diode is embodied in the region of the surface. The electron potential barrier can be embodied by virtue of the mirror surface bearing directly on the semiconductor material of the main body or on the dielectric coating. In this case, the electron flow from the main body in the direction of the metallic polarization grating is impeded by the electron potential barrier. In this context, laser light introduced into the semiconductor laser component can be detected since this influences the relationships-present in the resonator cavity-between the electromagnetic energy density and the free electrons induced thereby. In particular, a standing wave that manifests in the resonator cavity is influenced by the laser radiation penetrating into the resonator cavity.

It is advantageous for the polarization grating to be electrically connected to at least one electrical evaluation terminal, such that an electrical signal generated by electrons that have overcome the electron potential barrier is detectable at the electrical evaluation terminal. An evaluation unit can be connected to the electrical evaluation terminal in order to evaluate the signal. As a result, it is possible to provide a sensor device which is used for example in the evaluation of signals in the field of data communication. The laser light guided back into the semiconductor component can be guided as far as the emission region by means of a fiber-optic guide in order to optically couple it into the resonator cavity. The laser light to be coupled in may originate from a further semiconductor component optically coupled to the light guide at an opposite end thereof.

In order to ensure an efficient use of the semiconductor component in server hardware devices, for example, the Schottky diode can be configured such that the Schottky diode can detect high-frequency signals into the terahertz range that are induced by laser light reflected back into the main body or introduced by a light guide. In this case, the signals can detect signal sequences and/or modulations into the terahertz range.

Preferably, provision can be made for the polarization grating to be electrically connected to at least one of the electrical contacts. As a result, an electrical evaluation terminal can be obviated and the evaluation unit can be connected to the electrical terminal. For this purpose, the evaluation unit can be equipped with a filter that enables the Schottky diode signals to be evaluated.

It is preferred for a portion of at least one electrical contact to be embodied in arcuate fashion, the arcuate portion surrounding the emission region. In this case, the arcuate portion does not surround the entire emission region. The arcuate portion makes it possible to guide electrical energy uniformly into the active layer below the emission region.

With preference, grating elements can extend in comblike fashion from a concave side of the arcuate portion of the electrical contact over the emission region. The grating elements can be rectilinear extensions having free ends.

The grating elements of two mutually opposite arcuate portions can be arranged parallel next to one another, without having an electrical connection to one another. Preferably, the free ends of the grating elements are directed at the opposite arcuate portion of the electrical contact.

In a further embodiment, the polarization grating can be embodied in meanderlike fashion. In this case, it can be connected to an electrical evaluation terminal or an electrical contact.

The electrical contacts and the polarization grating can include gold, the electrical contacts and the polarization grating being able to be fabricated in a joint method step by way of so-called metallization of the surface.

It goes without saying that the features mentioned above and those yet to be explained below can be used not only in the respectively specified combination but also in other combinations.

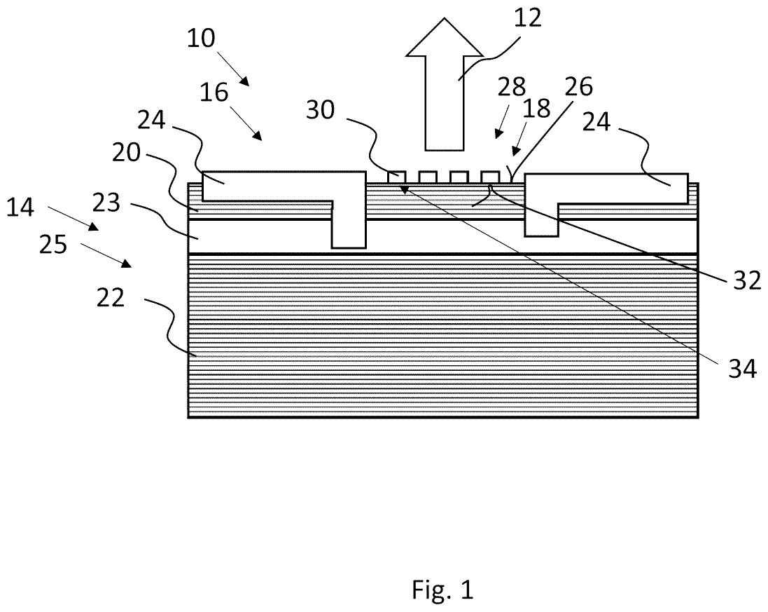

FIG. 1 illustrates a semiconductor component 10 for emitting laser light 12.

The semiconductor component 10 has a main body 14 having at least one mesa portion 16 with an emission region 18 for the laser light 12, which is assigned a first mirror portion 20, a second mirror portion 22 and an active portion 23 arranged between the two mirror portions 20, 22 and serving to generate the laser light 12.

The main body 14 of the semiconductor component 10 is constructed from a stack having functional layers for the laser operation. In particular, the semiconductor component 10 can be embodied as a so-called VCSEL (vertical cavity surface emitting laser), the propagation direction of the laser light 12 being oriented transversely with respect to the planes of extent of the functional layers.

The two mirror portions 20, 22 form a resonator cavity 25, in which the active layer 23 is excited to emit laser light. At least one subsection of the resonator cavity 25 is comprised by the mesa portion 16. The mirror portions 20, 22 include corresponding light-reflecting layers. On the first mirror 20, at least one electrical contact 24 can be arranged on an outwardly facing surface 26. The electrical contact 24 is provided for feeding electrical energy into the active portion 23.

The laser light contained in the resonator cavity 25 is emitted from the emission region 18 as coherent laser light 12. The emission region 18 is also arranged on the surface 26 of the first mirror portion 20, a metallic polarization grating 28 being positioned on said emission region.

Without the polarization grating 28, the semiconductor component 10 would emit unpolarized laser light 12. The polarization grating 28 enables a polarization of the emitted laser light 12 which is permanent and temperature-independent.

The metallic polarization grating 28 can be produced on the surface 26 of the main body 14 in a production step identical or similar to that for the at least one electrical contact 24. Both the metallic polarization grating 28 and the electrical contacts 24 can include gold. In this case, both the metallic polarization grating 28 and the electrical contact 24 can preferably consist of a gold alloy or, in particular, pure gold.

The polarization grating 28 is constructed from grating elements 30 preferably having at least partly straight portions. The polarization grating 28 has a mirror surface 32 facing the surface 26, said mirror surface reflecting the laser light 12 in addition to the mirror portions. The mirror surface 32 is arranged on the underside of the polarization grating 28 as oriented in the reading direction of FIG. 1 and bears on the surface 26. Preferably, each grating element 30 has a mirror surface 32.

The mirror surface 32 reflects the laser light 12 at the surface 26 into the main body 14 and increases the reflectivity of the resonator cavity 25. In order that the reflection of the laser lights 12 can take place efficiently, the mirror surface 32 has a very high surface quality. The surface quality more or less corresponds to the surface quality of the surface 26 of the main body 14. In order to ensure the surface quality even over a relatively long period of time, a dielectric coating can be provided on the surface 26 of the main body 14, and prevents the metal of the polarization grating 28 from diffusing in between the mirror surface 32 and the surface 26. For example, an oxide layer and/or an atomic layer of a dielectric material can be deposited, on which the mirror surface 32 bears and which acts as a diffusion barrier.

Electrons in the semiconductor material of the main body 14 are liberated by laser light 12 that is reflected back into the main body 14 and/or is introduced by a light guide, for example. In this case, the laser light 12 penetrating into the main body 14 influences the electromagnetic relationships within the resonator cavity 25, such that for example a standing wave that manifests in the resonator cavity 25 is influenced. Overall the electromagnetic energy density within the main body changes, which influences the energy level of the electrons. The liberated electrons may indicate laser light 12 absorbed by the main body 14.

A Schottky diode 34 forms between the metallic polarization grating 28, the mirror surface 32 of which bears on the surface 26, and the main body 14 produced from semiconductor material. The electron potential barrier can be embodied by virtue of the mirror surface 32 bearing directly on the semiconductor material of the main body 14 or on the dielectric coating. The Schottky diode 34 is distinguished by an electron potential barrier that prevents an undisturbed electron flow from the main body 14 into the polarization grating 28. Only electrons that have a sufficiently high energy level can overcome the electron potential barrier and penetrate into the polarization grating 28 from the main body 14.

In the field of server hardware devices, such a semiconductor component 10 comprising a Schottky diode 34 can be used as a detector for laser light 12 introduced into the main body 14 by a light guide. The laser light 12 to be coupled into the main body 14 may originate from a further semiconductor component 10 optically coupled to an opposite end of the light guide.

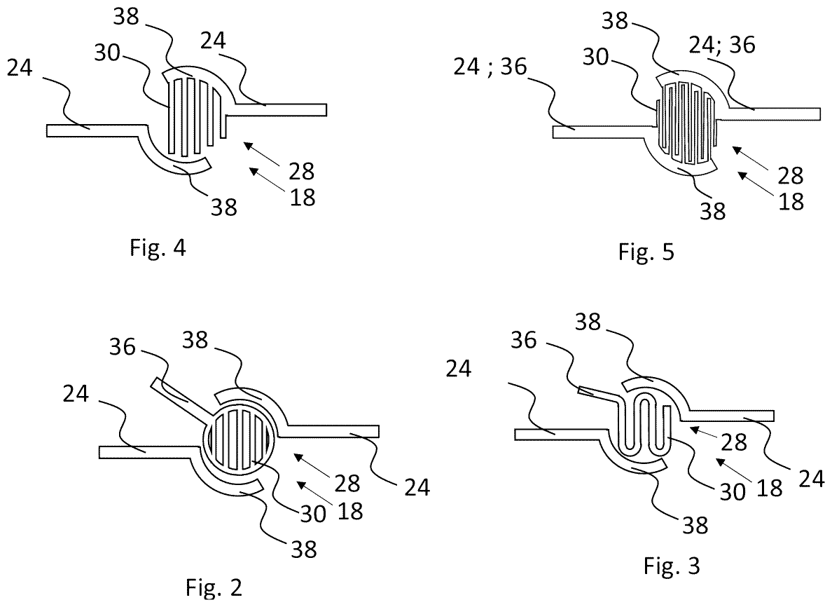

FIGS. 2 and 3 each show a polarization grating 28 from FIG. 1 which is electrically connected to at least one electrical evaluation terminal 36. The electrons that have overcome the electron potential barrier of the Schottky diode 34 can be evaluated by an evaluation unit connected to the electrical evaluation terminal 36. The signal sequences evaluated by this means can be in the terahertz range, such that there is a particular advantage of the application of a Schottky diode 34 in conjunction with the semiconductor component 10 in the field of data communication.

FIG. 2 illustrates an arrangement comprising a polarization grating 28 with an electrical evaluation terminal 36 and electrical contacts 24.

The polarization grating 28 is constructed from grating elements 30 electrically contacted with one another. The grating elements 30 are preferably parallel to one another. Purely by way of example, the grating elements 30 can be electrically connected to one another by a circumferential ring at their longitudinal ends. The electrical evaluation terminal 36 protrudes radially from the polarization grating 28.

The electrical contacts 24 have arcuate portions 38 extending around portions of the polarization grating 28 and thus the emission region 18. The concave sides of the arcuate portions 38 lie opposite one another in relation to the polarization grating 28.

FIG. 3 illustrates a further exemplary embodiment of an arrangement comprising a polarization grating 28 with an electrical evaluation terminal 36 and electrical contacts 24.

The electrical contacts 24 can be embodied in the same way as in FIG. 2. The polarization grating 28 is embodied in meanderlike fashion, the grating elements 30 being straight portions of the meanderlike polarization grating 28 that are arranged parallel to one another. The grating elements 30 are connected to one another by curved portions.

The meanderlike polarization grating 28 is preferably arranged only on the emission region 18. In particular, the polarization grating 28 is situated between the arcuate portions 38 of the electrical contacts 24.

The meanderlike polarization grating 28 is connected to an electrical evaluation terminal 36 provided for connecting and evaluation device.

FIG. 4 illustrates an exemplary embodiment in which the polarization grating 28 does not have a separate evaluation terminal 36 and in return is connected to an electrical contact 24.

In this embodiment, the evaluation unit is connected to the electrical contact 24 and can be equipped with a filter that enables the Schottky diode signals provided for evaluation to be filtered.

In the exemplary embodiment in FIG. 4, grating elements 30 extend in comblike fashion from a concave side of the arcuate portion 38 of a first electrical contact 24 over the emission region. The grating elements 30 can be rectilinear extensions having free ends directed at the concave side of the opposite arcuate portion 38 of a second electrical contact 24. In this case, the arcuate portion 38 of the second electrical contact 24 does not have protruding grating elements 30.

A further embodiment (not depicted) includes grating elements 30 of two mutually opposite arcuate portions 38 of electrical contacts 24 being arranged parallel next to one another. For example, the grating elements 30 of the opposite electrical contacts 24 can be arranged alternately next to one another, without having an electrical connection to one another. Preferably, the free ends of the grating elements 30 are directed at the opposite arcuate portion 38 of the electrical contact 24.

In accordance with FIG. 5, two comblike polarization gratings 28 can be provided, the grating elements 30 of which intermesh. The polarization gratings 28 can be connected to electrical contacts 24 provided for feeding electrical energy into the semiconductor component 10. Alternatively, the intermeshing grating elements 30 can be connected to evaluation terminals 36.

In all the exemplary embodiments, a dielectric coating can also be arranged on the polarization grating 28. It can also be arranged between the grating elements 30.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

10 Semiconductor component
12 Laser light
14 Main body
16 Mesa portion
18 Emission region
20 Mirror portion
22 Mirror portion
23 Active portion
24 Electrical contact
25 Resonator cavity
26 Surface
28 Polarization grating
30 Grating elements
32 Mirror surface
34 Schottky diode
36 Evaluation terminal
38 Arcuate portion

1. A semiconductor component for emitting laser light, comprising:
a main body having at least one mesa portion with an emission region for the laser light, the emission region comprising a first mirror portion, a second mirror portion, and an active portion arranged between the first mirror portion and the second mirror portion, the active portion serving to generate the laser light,
electrical contacts for feeding electrical energy into the active portion, and
a metallic polarization grating arranged on a surface of the main body on the emission region.

2. The semiconductor component as claimed in claim 1, wherein the polarization grating has a mirror surface facing a surface, the mirror surface configured to reflect the laser light into the main body in addition to the first mirror portion and the second mirror portion.

3. The semiconductor component as claimed in claim 1, wherein the surface is covered by a dielectric coating, such that the polarization grating bears on the coating.

4. The semiconductor component as claimed in claim 1, further comprising an electron potential barrier disposed between the polarization grating and the main body, such that a Schottky diode is formed in a region of a surface.

5. The semiconductor component as claimed in claim 4, wherein the polarization grating is electrically connected to at least one electrical evaluation terminal, such that an electrical signal generated by electrons that have overcome the electron potential barrier is detectable at the electrical evaluation terminal.

6. The semiconductor component as claimed in claim 4, wherein the Schottky diode is configured to detect high-frequency signals into a terahertz range that are induced by the laser light reflected back into the main body.

7. The semiconductor component as claimed in claim 1, wherein the polarization grating is electrically connected to at least one of the electrical contacts.

8. The semiconductor component as claimed in claim 7, wherein a portion of at least one electrical contact is configured in arcuate fashion and surrounds the emission region.

9. The semiconductor component as claimed in claim 8, wherein grating elements of the polarization grating extend in comblike fashion from a concave side of the arcuate portion of the electrical contact over the emission region.

10. The semiconductor component as claimed in claim 7, wherein grating elements of the polarization grating extend in comblike fashion from two mutually opposite arcuate portions of the electrical contacts, the grating elements extending from a first one of the two arcuate portion and the grating elements extending from a second one of the two arcuate portion are arranged parallel next to one another, without having an electrical connection to one another.

11. The semiconductor component as claimed in claim 1, wherein the polarization grating is configured in meanderlike fashion.

12. The semiconductor component as claimed in claim 1, wherein the polarization grating comprises gold.
